(19) United States
(12) Patent Application Publication
(10) Pub. No.: US 2020/0252056 A1
(43) Pub. Date: Aug. 6, 2020

(54) SYSTEM AND METHOD FOR CALIBRATING FILTER MISMATCH IN MULTI-INPUT MULTI-OUTPUT COMMUNICATION SYSTEMS

(71) Applicant: Saudi Arabian Oil Company, Dhahran (SA)

(72) Inventor: Khalid A. ALSUHAILI, Dhahran (SA)

(21) Appl. No.: 16/267,435

(22) Filed: Feb. 5, 2019

(51) Int. Cl. H03H 17/04; H04B 7/0417; H04B 7/06

(52) U.S. Cl. CPC H03H 17/04; H04B 7/0417; H03H 2218/025; H03H 2218/06; H04B 7/0652

(57) ABSTRACT

A system and method for calibrating mismatch between the transmit and receive filters of communication nodes in MIMO communications systems. The exemplary calibration algorithm involves two nodes communicating back-and-forth and, based on the received signal, the receiving node calculating an updated calibration matrix and calculating parameters for communicating over the best singular mode (BSM). According to a salient aspect, the updated calibration matrix and the BSM parameters can be calculated as a function of a difference between previous estimates thereof and the current received signal. The calculated BSM parameters and calibration matrix can then be used to transmit a signal back to the other node, which similarly performs the calibration matrix and BSM parameter calculation steps. The calibration algorithm can be repeated by the nodes a suitable number of iterations for each nodes' respective calibration matrix to impose reciprocity on the effective communication channel therebetween.

### FIELD OF THE DISCLOSURE

The present invention relates to wireless communication systems, in particular, systems for calibrating mismatched filters used in the analog front-end of multiple-input multiple-output communication systems.

### BACKGROUND OF THE DISCLOSURE

Multiple-input multiple-output (MIMO) refers to communications system in which multiple antennas are provided at both the transmitting and receiving nodes. MIMO communication methods multiply the capacity of a radio link by using the multiple transmission and receiving antennas to exploit multipath propagation techniques. The use of multiple antennas allows for manipulating the signals transmitted or received on each antenna of a node to achieve a better performance than a single-input single-output (SISO) system. Multi-user MIMO (MU-MIMO) is a set of multiple-input and multiple-output (MIMO) technologies for wireless communication, in which a set of users or wireless terminals, each with one or more antennas, communicate with each other. In contrast, single-user MIMO considers a single multi-antenna transmitter communicating with a single multi-antenna receiver.

Many signal processing algorithms implemented in communication systems assume the reciprocity of the forward and reverse communication channels between two communicating nodes. MIMO beamforming techniques are just one example. However, this reciprocity condition is not guaranteed. For instance, a lack of reciprocity can be caused by a physical mismatch between the Front End Transmit Filter (FETF) and the Front End Receive Filter (FERF) of a given node. Specifically, due to the production variations of the various components of the node, each transmit or receive chain introduces a unique gain and phase rotation between the baseband processor and its corresponding antenna.

Therefore, the efficient calibration of MIMO systems is an essential topic in the design phase and during operation. One way to deal with this hardware mismatch is by calibrating transmit and receive filters using additional RF hardware. Using additional RF hardware costs more resource and the RF hardware occupies space. What is needed is an effective approach for calibrating the hardware mismatch of front-end filters without reliance on additional RF hardware.

It is with respect to these and other considerations that the disclosure made herein is presented.

### SUMMARY OF THE DISCLOSURE

According to an aspect of the present disclosure, a method for calibrating filter mismatch of a MIMO communication system is disclosed. The method comprises the step of receiving a first signal at a first communication node, wherein the signal is transmitted by a second communication node to the first node through a wireless communication channel. From the received signal, the first node determines an estimate of an output singular vector and a gain value of a channel matrix from the first communication node to the second communication node. In addition, the first node calculates an estimate of a calibration matrix. More specifically, the calibration matrix estimate is calculated as a function of the received signal, a previous estimate of the output singular vector, a previous estimate of the gain value and a previous estimate of the calibration matrix. The method also includes the step of the first node transmitting a second signal over the channel. More specifically, the signal is transmitted according to the estimate of the output singular vector, gain value and channel matrix calculated by the first node.

According to another aspect, a MIMO communication system is disclosed. The system comprises a a first communication node that includes a receiver. The receive is configured to receive signals transmitted over a wireless communication channel, including a first signal transmitted by a second node. The first node also includes a beamforming module encoded in a processor of the node. The beamforming module configures the processor to determine, from the received signal, an estimate of an output singular vector and a gain value of a channel matrix from the first node to the second node. The first node also includes a calibration module that configures the processor to calculate, based on the received signal, an estimate of a calibration matrix. More specifically, the calibration matrix estimate is calculated as a function of the received signal, a previous estimate of the output singular vector, a previous estimate of the gain value and a previous estimate of the calibration matrix. Furthermore, the node includes a transmitter that is configured to transmit a second signal over the channel. In particular, the signal is transmitted according to the estimate of the output singular vector, gain value and channel matrix calculated by the first node weighted according said subcarrier weights over the sub carriers.

These and other aspects, features, and advantages can be appreciated from the accompanying description of certain embodiments of the invention and the accompanying drawing figures and claims.

### BRIEF DESCRIPTION OF THE DRAWING FIGURES

FIG. 1 illustrates an exemplary MIMO communication system which can be used in conjunction with exemplary embodiments of the present invention;

FIG. 2 is a block diagram illustrating transmitter and receiver structures for an exemplary communication node that can be used in the system of FIG. 1;

FIG. 3 is a block diagram of an equivalent SVD representation of the input-output model for the system of FIG. 1;

FIG. 4 is a block diagram of the exemplary MIMO system of FIG. 1 and showing functional operations performed at Nodes X and Y for communicating using a best singular mode beamforming algorithm and implementing a calibration algorithm in accordance with one or more embodiments of the invention;

FIG. 5 is a high-level flow-diagram further illustrating a method in which MIMO Nodes X and Y communicate using a best singular mode beamforming algorithm and a calibration algorithm in accordance with one or more embodiments of the invention;

FIG. 6A is a graph illustrating the performance of the exemplary calibration algorithm in estimating and updating the calibration matrices generated in connection with testing under given test parameters, specifically, values of parameter ζ;

FIG. 6B is a graph illustrating the performance of the exemplary calibration algorithm in estimating and updating the calibration matrices generated in connection with testing under given test parameters, specifically, values of parameter Δ;

FIG. 7A is a graph illustrating the performance of a node implementing the exemplary calibration algorithm compared to an un-calibrated system, specifically, the performance measure shown is the mean squared error of the estimated singular value using a BSM semi-blind algorithm; and

FIG. 7B is a graph illustrating the performance of system configurations implementing the exemplary calibration algorithm compared to un-calibrated system configurations, specifically, the performance measure shown is the mean squared of the difference angle between the optimal input and output vectors determined using the BSM semi-blind algorithm.

### DETAILED DESCRIPTION OF CERTAIN EMBODIMENTS OF THE DISCLOSURE

By way of overview and introduction, a system and method for calibrating mismatches in the transmit and receive filters of multi input multi output (MIMO) communications systems is disclosed. The exemplary calibration systems and methods disclosed herein are configured to compensate for a lack of channel reciprocity caused by, for instance, a physical mismatch between the Front End Transmit Filter (FETF) and the Front End Receive Filter (FERF) of MIMO communication nodes.

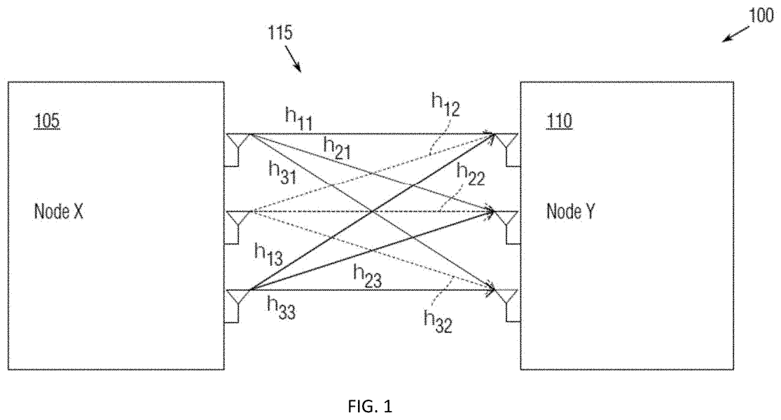

FIG. 1 is a block diagram illustrating an exemplary communication system 100 within which the calibration systems and methods can be implemented. The system 100 is a MIMO system comprising two nodes, Node X 105 and Node Y 110, that are capable of transmitting and receiving data. The system of the present disclosure is an N×M system, wherein N and M are the number of antennas at Node Y and X, respectively. As shown in FIG. 1, the nodes communicate over wireless channels 115, which can be slow block fading channels. As would be understood, the communication can take place between any of the M antennas of

Node X and any of the N antennas of Node Y. While the system 100 is shown as having two nodes, it should be understood that the system can comprise any number of nodes.

The system 100 can be configured for wireless communications using time division multiple access (TDMA). As would be understood, TDMA is a channel access method that allows multiple stations to share and use the same transmission channel by dividing signals into different time slots. Users transmit in rapid succession, and each one uses its own time slot. Thus, in TDMA, multiple devices may share the same frequency channel but only use part of its capacity. The calibration systems and methods can similarly be utilized in communications systems that employ other suitable channel access methods.

While the physical wireless communication path 115 between nodes can be reciprocal, due to the production variations of the transmitter/receiver components of the nodes, each transmit or receive chain can introduce a unique gain and phase rotation between the baseband processor and its corresponding antenna. As a result, the effective communication channel between the nodes are not reciprocal. According to a salient aspect, the nodes 105 and 110 can be configured to implement an iterative algorithm that calibrates the mismatch between the FETF and the FERF without the need for any additional circuitry.

As a non-limiting example, the nodes are described herein as being configured to calibrate for filter mismatch in connection with MIMO communications occurring over best singular mode (BSM). An exemplary system and method for identifying the BSM of a reciprocal MIMO channel and performing communications over the BSM is described, for example, in Gazor, S., & AlSuhaili, K. (2010, July), “Communications over the Best Singular Mode of a Reciprocal MIMO Channel,” Communications, IEEE Transactions on, 58 (7), 1993-2001 (“NPL Gazor-AlSuhaili. Identifying BSM serves to define the transmit and receive beamformers at the communicating nodes. In this regard, NPL Gazor-AlSuhaili proposes a distributed algorithm in which two nodes communicate iteratively back and forth and independently and jointly implement the BSM estimation algorithm so as to identify the BSM without reliance on channel-state information (CSI) feedback. The algorithm proposed in NPL Gazor-AlSuhaili estimates the triplet of channel matrix H and, with each received signal, the receiving node forms an updated “estimate.”

The BSM communication algorithm of NPL AlSuhaili, however, operates on the assumption that the transmitters and receivers of the nodes are optimal beamformers and that the forward and reverse communication channels are reciprocal. This assumption, however, is not always satisfied in practice and, thus, the BSM of the forward and reverse channels will not necessarily be the same. Accordingly, the disclosed embodiments improve upon the iterative approach for identifying BSM disclosed in NPL AlSuhaili by implementing an iterative calibration algorithm that compensates for the filter mismatch at the nodes and determines the BSM for each node, respectively. While BSM is an exemplary beamforming algorithm described herein, it should be understood that the exemplary systems and methods for filter mismatch calibration disclosed herein can similarly be applied in connection with other beamforming or power allocation techniques.

According to a salient aspect of the present disclosure, the nodes are configured to include a calibration module, which is realized in the baseband processor of the node's transmitter/receiver component rather than using RF hardware. The calibration module serves to define a matrix of calibration coefficients which are iteratively calculated according to the calibration algorithm further described herein. Generally, the calibration matrix is a diagonal matrix that serves to condition the signals transmitted and/or received by a given node to compensate for the mismatch between the transmit and receiver chains of that node. The calibration algorithm is jointly performed by both Nodes X and Y and serves to define the coefficients of respective calibration matrices at both nodes.

In accordance with one or more of the disclosed embodiments, each node is configured to perform calibration by multiplying a received signal (or a transmitted signal) by a respective diagonal calibration matrix and, based on the received signal, update the entries of the calibration matrix recursively.

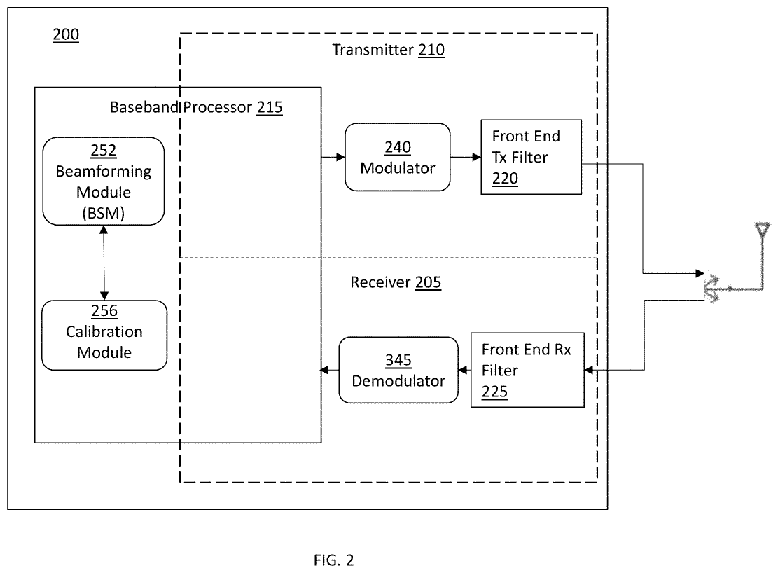

FIG. 2 is high-level block diagram illustrating the general structure of an exemplary transmitter/receiver (also called a transceiver) 200 which can be provided at each of Node X 105 and Node Y 110 of the system 100 and can be configured to perform the exemplary filter mismatch calibration and beamforming operations among other known MIMO communications techniques. It should be understood that, in addition to the components specifically described herein, the exemplary transceiver 200 can include any components of a MIMO TDMA transmitter and receiver device, as are known in the art.

As shown, the transceiver can include a receiver (RX) component 205 and a transmitter (TX) component 210. The RX and TX components can include the analog and digital signal processing components suitable for enabling communications to and from the node. For instance, the TX component can include a front-end transmit filter 220 and a modulator 240, similarly, the RX component can comprise a front-end receive filter 225 and a demodulator. The FX and TX components of the transceiver 200 can further include a baseband processor 215 configured to perform various operations relating to wireless communications and processing of the information and related operations. For instance, the baseband processor can include encoders and decoders signal mapping modules among other functional modules. As would be understood, in some exemplary implementations, the processor can be programmed with encoded instructions that, when executed by the processor, configure the processor to perform the various operations described herein.

The transceiver 200 can also include a beamforming module 252 and a calibration module 256 that, as shown in FIG. 2, can be implemented by the baseband processor 215. Generally, the beamforming module can configure the transceiver to perform beamforming using two separate beamformers, namely, a transmit beamformer for wirelessly transmitting data, and a receive beamformer for receiving data.

The calibration module 256 can configure the transceiver 200 to apply the calibration algorithm for calculating a calibration matrix. As noted, the calibration matrix is a diagonal matrix that can be used to condition the signals transmitted or received by a given node to compensate for the mismatch between the Tx and Rx chains of that node. Physical mismatch between the Front End Transmit Filter (FETF) and the Front End Receive Filter (FERF) of respective nodes is resolved by the nodes multiplying a respective calibration matrix with the sent or received signals. Consequently this imposes reciprocity on the effective forward and reverse channels between the nodes.

The calibration algorithm aims at accurately estimating the calibration matrix through iteratively updating the calibration matrix. The updating involves calculating the calibration matrix as a function of a previous estimation of the calibration matrix and the observation of the current signal received by the transceiver 200. More specifically, the previous estimate and current received signals can be differentially weighted by the calibration module according to a cost function. For instance, the calibration module can be configured to put a weight factor on the previous estimate of the diagonal calibration matrix relative to the current received signal. The estimation of the calibration matrix can also be a function of determined parameters relating to the BSM (e.g., an output vector and gain) determined by the beamforming module 252.

As further described herein, the transceiver can be configured to execute the exemplary calibration algorithm in conjunction with the exemplary BSM estimation algorithm so as to iteratively update the gain and output vector BSM parameters and the calibration matrix, respectively. This approach enables the node to communicate using BSM despite the existence of front-end filter mismatch.

### Model MIMO TDMA System and Problem Formulation

With continued reference to FIGS. 1-2, to further illustrate the exemplary systems and methods for filter mismatch calibration, following is a brief discussion of the model of the exemplary communication system 100 along with the formulation of the problem addressed by the exemplary filter-mismatch calibration algorithm. For clarity, small bolded letters are used to reference vectors and capital bolded letters reference matrices. The set of m-dimensional complex vectors are shown by [symbol] m and [symbol] m×n shows the set of m×n complex matrices. The i^{th} column of matrix A is shown with [A]ⁱ and [A]^{ij} shows the (i, j)^{th} entry of A. The k dimensional identity matrix is denoted by Iₖ. Notations ∥⋅∥, (⋅)^{T}, (⋅)* and (⋅)^{H} are used for the Frobenius norm, transpose, conjugate and hermitian of a vector/matrix, respectively.

As described herein, the model MIMO system 100 is assumed to be equipped with M antennas at the base station (e.g., Node X) and N antennas at the terminal (e.g., Node Y) operating in a Time Division Multiple Access (TDMA) mode in the same frequency band. It should be understood that either Node X or Y can operate as a base station or terminal. At the base station, the carrier frequency is assumed to be the same across all transmit chains since they share the same set of oscillators. Similarly, the base station down-conversion frequency is also assumed to be the same across all receive chains. Preferably, the uplink and the downlink carrier frequency should be the same for TDMA mode.

The physical channel matrix representing the path from Node X to Y is denoted by H_{xy} and the path from Node Y to X is H_{yx}. The physical channel matrix is assumed to be reciprocal, that is,

H_{xy}=H_{yx}^{T} [symbol] H. (1)

Assuming that the Singular Value Decomposition (SVD) of H is UΣV^{H}, define the transmit and the receive beamformers at Node X, bₓₜ=v₁, and bₓᵣ=v₁, and similarly at Node Y as b_{yt}=u*₁ and b_{yr}=u*₁. The transmitted signals from Node X and Y are given by:

Tₓ=bₓₜdₓ^{T}, (2a)

T_{y}=b_{yt}d_{y}^{T}, (2b)

where dₓ and d_{y} are two column vectors represent the data frames to be sent by Node X and Y, respectively. The received signal matrices, R_{y}∈ [symbol] ^{N×L} at Node Y and Rₓ∈ [symbol] ^{M×L} at Node X (L is the length of the sent data frame), are given by

R_{y}=HTₓ+N_{y}=σ₁u₁dₓ^{T}+N_{y}, (3a)

Rₓ=H^{T}T_{y}+Nₓ=σ₁v*₁d_{y}^{T}+Nₓ, (3b)

where Tₓ∈ [symbol] ^{M×L} and T_{y}∈ [symbol] ^{N×L} are the transmitted signal matrices from Node X and Y respectively (Tₓ and T_{y} are mappings of the frames dₓ∈ [symbol] ^{L×1} and d_{y}∈ [symbol] ^{L×1} intended to be sent by Node X and Y, respectively). N_{y}∈ [symbol] ^{N×L} and Nₓ∈ [symbol] ^{M×L} are the complex white Gaussian noise matrices with i.i.d., zero mean and v² variance elements. In this exemplary model, it is assumed that, the channel matrix H∈ [symbol] C^{N×M} is constant during during the channel training period even though the proposed BSM estimation algorithms are capable of adapting to any sudden changes in the communication channel. For slow block fading channels, the channel matrix H∈ [symbol] ^{N×M} is constant during multiple frames dₓ or d_{y}. The elements of H are assumed to be i.i.d. circularly symmetrical complex Gaussian random variables, with zero mean and unit variance. The channels are assumed to be unknown to both, the transmitter and the receiver.

The estimate of the transmitted data frames at the receiving nodes is given by

$$\begin{matrix}{\hat{d}}_{x}^{T} = \frac{1}{{σ}_{1}} {b}_{yr}^{T} {R}_{y} , & ( 4 a ) \\ {\hat{d}}_{y}^{T} = \frac{1}{{σ}_{1}} {b}_{xr}^{T} {R}_{x} . & ( 4 b )\end{matrix}$$

Note that when the forward channel matrix is the reciprocal of its counterpart, the receive beamformer at a certain node is the same as the transmit beamformer at that node. However, when they lack the reciprocity, the above statement is not correct anymore, as the singular modes in the forward direction are different from the ones in the reverse direction. In such a case, two different channel matrices can be identified, the channel matrix in the forward direction from Node X to Node Y, H_{X→Y}, and the channel matrix in the reverse direction from Node Y to Node X, H_{Y→X}X.

The performance of the MIMO system 100 can depend on the properties of the channel response matrix, H, especially on its rank. For example, it is understood that correlation among the sub-channels has important impact on the communication performance. If H is known at both transmitter and receiver, the channel is equivalent to r parallel SISO AWGN channel where r is the rank of H. The gain of each of these r channels is the corresponding singular value of H. According to the water-filing theorem, which is well known, more power should be allocated for transmission of signals over stronger singular modes of the channel in order to maximize the channel capacity. However, this mechanism requires the full knowledge of H at both the transmitter and receiver nodes in order to design an optimal pre-coder and decoder.

Another approach to improving channel capacity that can be utilized when H is not known at both the transmitter and receiver is for the nodes to transmit only over the best singular mode (BSM). Transmitting only over the BSM is a beamforming approach which uses only one optimal beamformer at the transmitter and one at the receiver. These beamformers represent the singular vectors of H associated with the largest singular values. For highly correlated channels with a rank r=1, this approach can be optimal or near-optimal. Also, when the ratio of the transmit power to receive noise variance is smaller than

$$\frac{1}{{σ}_{2}^{2}} \text{?} - \frac{1}{σ \text{?}} , \\ \text{?} \text{indicates text missing or illegible when filed}$$

the optimal water-filling algorithm suggests using only the BSM, and in such a case, this approach is capacity optimal, where σ₁ and σ₂ are the two most dominant singular values of the channel response. This is because the water filling algorithm allocates power to less number of the best modes as the transmit power is reduced, which is equivalent to reducing the SNR. As noted, for example and without limitation, the systems and methods for filter mismatch calibration are described herein in the context of MIMO communications occurring over BSM.

With reference to FIG. 2, which is a block diagram of the equivalent SVD representation of the input-output model where r=Rank (H), the Singular Value Decomposition theorem states that there exists a factorization of H_{X→Y} of the form

H_{X→Y}=UΣV^{H}=Σᵢ₌₁^{r}σᵢuᵢvᵢ^{H}, where r=Rank (H)

where U=[u₁, u₂, . . . , uᵣ]∈ [symbol] ^{N×r} and V=[v₁, v₂, . . . , vᵣ]∈ [symbol] ^{M×r} are two matrices with orthonormal columns, the matrix Σ=diag(σ₁, σ₂, . . σᵣ) is a r×r diagonal matrix with non-negative real numbers on the diagonal such that σ₁≥σ₂≥ . . . ≥σᵣ.

The matrix V contains a set of ortho-normal “input” basis vector directions for H_{X→Y}, and its columns are often called the right singular vectors. The matrix U contains a set of ortho-normal “output” basis vector directions for H_{X→Y}, and its columns are often called the left singular vectors. The matrix Σ contains the singular values, which can be thought of as scalar “gain controls” by which corresponding inputs are multiplied to give corresponding outputs.

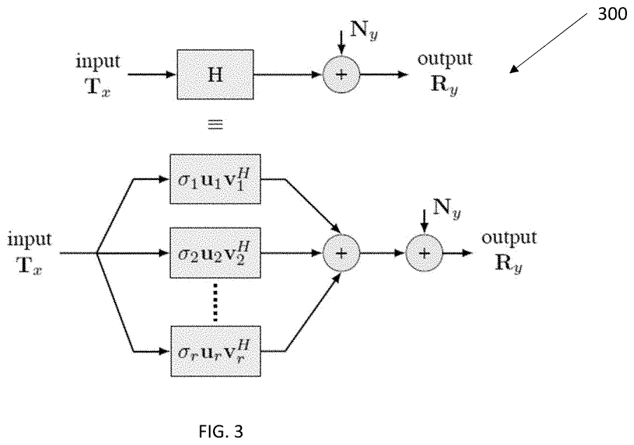

FIG. 3 also shows the channel H_{X→Y} decomposed into its singular modes. A MIMO channel is equivalent to multiple Rank(H) SISO parallel channels provided that singular modes are known at both nodes. The optimal water-filling solution for power allocation over multiple parallel channels suggests to only use the BSM if the transmit power is limited. Thus, the best singular mode (σ₁, v₁, u₁) is preferably selected to transmit a data frame from Node X to Node Y over the channel H_{X→Y}.

Because the forward and reverse channels are not reciprocal, the singular modes in the forward direction will be different from the ones in the reverse direction. Accordingly, the channel matrices in the X→Y and Y→X direction can be respectively represented by their singular value decomposition as follows:

H_{X→Y}=UΣV^{H}, (5a)

H_{Y→X}=QΓP^{H}, (5b)

In view of the foregoing, for Node X to be able to perform beamforming using, for example, the best singular mode, it can be configured to utilize two different beamformers, a transmit beam former, bₓₜ=v₁, when sending data and a receive beamformer, bₓᵣ=q*₁, when receiving data. Similarly, Node Y can be configured to include a transmit beamformer, b_{yt}=p₁, and a receive beamformer, b_{yr}=u*₁.

As noted, due to the production variations of the various components of the transceivers, each transmit or receive chain introduces a unique gain and phase rotation between the baseband processor and its corresponding antenna. At Node X, the effect can be represented by a baseband transmit and receive diagonal filters Gₓₜ and Gₓᵣ, respectively with entries gₓₜ_{ₘ}, m=1, . . . , M for the m^{th} transmit chain and by another baseband filter with entries, gₓᵣ_{ₘ}, m=1, . . . , M for the corresponding receive chain. The counterparts of these parameters, at Node Y, at the n^{th} terminal antenna are similarly defined. In a more concise matrix representation, the effect of the diagonal filters can be further defined as:

Gₓₜ [symbol] diag[gₓₜ_{₁}, . . . ,gₓₜ_{_{M}}],

Gₓᵣ [symbol] diag[gₓᵣ_{₁}, . . . ,gₓᵣ_{_{M}}],

G_{yt} [symbol] diag[g_{yt}_{₁}, . . . ,g_{yt}_{_{M}}],

G_{yr} [symbol] diag[g_{yr}_{₁}, . . . ,g_{yr}_{_{M}}] (6)

The received signal matrices are then given by

R_{y}=G_{yr}HGₓₜTₓ+N_{y}, (7a)

Rₓ=GₓᵣH^{T}G_{yt}T_{y}+Nₓ, (7b)

where G_{yr}HGₓₜ represents H_{X→Y} (the equivalent channel of the forward path) and GₓᵣH^{T}G_{yt} represents H_{Y→X} (the equivalent channel of the reverse path).

According to the SVD given in (5a) and (5b), the transmitted signals from Node X and Y can be represented by:

Tₓ=v₁dₓ^{T}bₓₜdₓ^{T}, (8a)

T_{y}=p₁d_{y}^{T}b_{yt}dₓ^{T}, (8a)

The estimate of the transmitted data at the receiving nodes can be represented by:

$$\begin{matrix}{\hat{d}}_{x}^{T} = \frac{1}{{σ}_{1}} {u}_{1}^{H} {R}_{y} = \frac{1}{{σ}_{1}} {b}_{yr}^{T} {R}_{y} , & ( 9 a ) \\ {\hat{d}}_{y}^{T} = \frac{1}{{γ}_{1}} {q}_{1}^{H} {R}_{x} = \frac{1}{{γ}_{1}} {b}_{xr}^{T} {R}_{x} . & ( 9 b )\end{matrix}$$

The foregoing indicates that unless Gₓₜ=Gₓᵣ and G_{yt}=G_{yr}, the respective channels are not reciprocal and the exemplary BSM estimation algorithm could perform poorly due to the lack of reciprocity on which the power iteration method depends.

As such, according to one or more embodiments, the nodes of the exemplary MIMO communication system 100 can be configured to implement the filter-mismatch calibration algorithms further described herein.

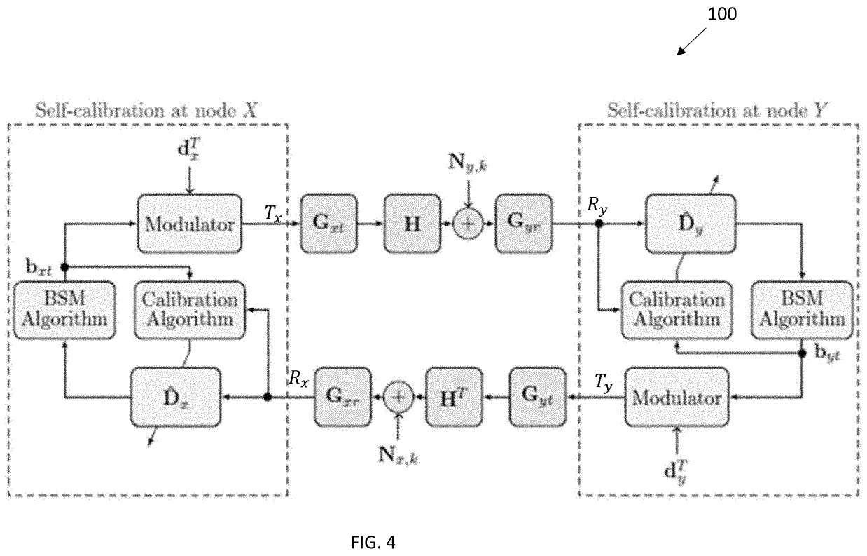

FIG. 4 is a functional block diagram of the exemplary MIMO system 100 and further illustrates the beamforming and calibration operations performed by each of Nodes X and Y as further described herein.

As noted, to resolve the physical mismatch between the Front End Transmit Filter (FETF) and the Front End Receive Filter (FERF), each node can be configured to multiply a received signal by a diagonal matrix Dₓ∈diag( [symbol] ^{M×M}), at Node X, and D_{y}∈diag( [symbol] ^{N×N}), at Node Y, and update its entries recursively. The effective channel matrices then become

H′_{X→Y}=D_{y}H_{X→Y}

H′_{Y→X}=DₓH_{Y→X} (18)

wherein H′_{X→Y}=H′_{Y→X}^{T}.

Both Nodes X and Y are configured to define a respective calibration matrix such that its multiplication with the sent or received signals serves to impose reciprocity on the effective channel matrices H′_{X→Y} and H′_{Y→X}. In other words, it is preferable for H′_{X→Y}=H′_{Y→X}. It should noted that, in practice, users might move and the physical response H might vary with time. As such, the nodes are configured to calculate the compensation matrix such that H′_{X→Y}=H′_{Y→X} holds independent of H.

Lemma 1: the necessary and sufficient condition for having:

D_{y}G_{yr}HGₓₜG_{yt}HDₓGₓᵣ. (11)

for all H∈ [symbol] ^{N×M} is that

[D_{y}]ᵢᵢ[G_{yr}]ᵢᵢ=[G_{yt}]ᵢᵢ, ∀i=1, . . . N, (12a)

[Dₓ]ⱼⱼ[Gₓᵣ]ⱼⱼ=[Gₓₜ]ⱼⱼ, ∀j=1, . . . M, (12b)

Proof 1: Equation (11) can be concluded from equation (12). Using the fact that all involved matrices except H are diagonal, the (i, j)^{th} element of (11) can be written as

[D_{y}]ᵢᵢ[G_{yr}]ᵢᵢ[H]ᵢⱼ[Gₓₜ]ⱼⱼ=[G_{yt}]ᵢᵢ[H]ᵢⱼ[Dₓ]ⱼⱼ[Gₓᵣ]ⱼⱼ. (13)

The foregoing implies that the system must either have [H]ᵢⱼ=0 or equation (12). Since equation (13) must be satisfied for all H including some non-zero [H]ᵢⱼ, the system must have (12).

In practice, during the calibration process, some of the elements of H might be very small, i.e., [H]ᵢⱼ≈0 might hold instead of (12a) and (12b). Therefore, during the calibration process, enough number of realizations of H can be preferable to ensure that (12a) and (12b) hold accurately, which provides that (11) is almost satisfied for all new possible realizations of H− [symbol] ^{N×M} during normal operation of the system.

In the context of the model MIMO system and problem formulation described above, an exemplary filter-mismatch calibration algorithm according to one or more embodiments of the present disclosure is further described herein. The exemplary systems and methods for filter-mismatch calibration provide an iterative approach for identifying BSM by the nodes in addition to defining a calibration matrix that compensates for the filter mismatch at the nodes.

As noted, the two nodes of the MIMO communication system 100, Node X 105 and Node Y 110 can each include a transceiver 200, comprising a beamforming module 252 and calibration module 256 that configure the nodes to iteratively and reciprocally communicate (i.e., back-and-forth) over the channel 115 and, based on the received signals, execute one or more steps of the BSM and filter mismatch calibration algorithms further described herein.

Generally, with each iteration, the algorithm involves, upon receipt of a received signal by a node, the calibration module 256 defining or “estimating” a calibration matrix and the beamforming module 252 estimating the BSM. According to a salient aspect, the newly calculated estimate of the calibration matrix can be calculated as a function of the difference between a previous estimate of the calibration matrix and the current received signal. Parameters relating to the BSM (e.g., u and σ for Node Y or q and γ for Node X) can be similarly determined by the beamforming module based on a previous estimate thereof and the current received signal. Thereafter, the receiving node utilizes the updated BSM and calibration matrix to transmit a signal back to the other node, which similarly performs the BSM and calibration matrix calculation steps. In some implementations, the process for updating the calibration matrix can be performed for each received signal. In addition or alternatively, the calibration matrix can be re-calculated at prescribed intervals, for instance, after a prescribed a number of iterations, after BSM has been estimated or as a function of other conditions.

Accordingly, the exemplary calibration algorithm and BSM algorithm can be iteratively repeated by Nodes X and Y and, with each iteration, the nodes each incrementally and adaptively update one or more of the respective estimate of the calibration matrix and the BSM parameters. It should be understood that the step of calculating the calibration matrix can be referred as “updating” or calculating an “updated” estimate, because it can be calculated as a function of a previously defined calibration matrix (e.g., one calculated during a prior iteration or defined during initialization). Similarly, because the BSM parameters are calculated with each received signal based on a previously calculated or previously defined BSM, the step for calculating BSM is also referred to as “updating” or calculating updated transmit weights.

It should be understood that, in some implementations, the aforementioned steps can also be preceded by one or more initialization steps by which the nodes respectively define an initial calibration matrix and/or BSM parameters that can then be updated through subsequent iterations.

The exemplary systems and methods for filter-mismatch calibration will be further appreciated in view of the following detailed discussion of the exemplary MIMO system 100 model and modified in accordance with the exemplary embodiments of the present disclosure. For simplicity the exemplary system and steps of the calibration and BSM estimation algorithms are described in the context of Node X transmitting a signal to Node Y over the channel in the X→Y direction and Node Y performing the filter mismatch calibration and BSM determination steps based on the received signal.

In an exemplary configuration, the calibration matrix D_{y} (at Node Y) can be defined by the exemplary calibration algorithm according to the following cost function, the minimization of which satisfies the requirements H′_{X→Y}=H′_{Y→X}^{T}:

$$\{ \begin{matrix}f ( σ , u , D ) = {μ ( σ - {\hat{σ}}_{1 , k - 1} )}^{2} + μ {‖ \hat{u} - \vert {\hat{u}}_{1 , k - 1} ‖}^{2} + \\ ζ {‖ D - {\hat{D}}_{y , k - 1} ‖}^{2} + {‖ {DR}_{y , k} - σ {ud}_{x , k}^{T} ‖}^{2} \\ ( {\hat{σ}}_{1 , y , k} , {\hat{u}}_{1 , k} , {\hat{D}}_{y , k} ) = arg {min}_{σ , u , D} ( f ( σ , u , D ) ) , \\ s . t . {D}_{y , k} ∈ diag ( {C}^{N \times N} ) , \\ {\hat{u}}_{1 , k}^{H} {\hat{u}}_{1 , k} = 1 , \\ {\hat{σ}}_{1 , y , k} \geq 0\end{matrix} , \qquad ( 14 )$$

\hat{σ}_{1,y,k}, û_{1,k} and \hat{D}_{y,k} represent the estimate of the actual values of σ_{1,y}, u₁ and D_{y} at iteration k, respectively. The parameters μ and ζ define the step sizes of updating \hat{σ}_{1,y}, û₁ and \hat{D}_{y}, respectively.

Assuming that a previous estimate of σ_{1,y}, u₁ and D_{y} has been defined, or a guess is available from previous iteration, to solve the optimization problem (14) with respect to D_{y,k}, the algorithm can be configured to approximate u by û_{1,k-1} and σ by û_{1,k-1}, so (1) reduces to

$$\{ \begin{matrix}f ( D ) = ζ {‖ D - {\hat{D}}_{y , k - 1} ‖}^{2} + {‖ {DR}_{y , k} - {σ}_{1 , y , k - 1} {u}_{1 , k - 1} {d}_{x , k}^{T} ‖}^{2} \\ {\hat{D}}_{y , k} = arg {min}_{D} ( f ( D ) ) , \\ s . t . {D}_{y , k} ∈ diag ( {C}^{N \times N} ) .\end{matrix} \qquad ( 15 )$$

In addition, setting

$$\frac{\partial f}{\partial {\hat{D}}_{y , k}^{*}} = 0 in ( 15 )$$

and based on the fact that \hat{D}_{y,k} is diagonal results in:

\hat{D}_{y,k}=(ζ\hat{D}_{y,k-}+\hat{σ}_{1,k-1}diag(û_{1,k-1}d_{x,k}^{T}R_{y,k}^{H}))(ζI+diag(R_{y,k}R_{y,k}^{H}))⁻¹ (16)

Furthermore, equation (16) can be written in terms of the components of D_{y,k} as follows

$${[ {\hat{D}}_{y , k} ]}_{ii} = \frac{1}{ζ + {‖ {[ {R}_{y , k} ]}^{i} ‖}^{2}} ( {ζ [ {\hat{D}}_{y , k - 1} ]}_{ii} + {{\hat{σ}}_{1 , k - 1} [ {\hat{u}}_{1 , k - 1} ]}_{i} {{d}_{x , k}^{T} ( {[ {R}_{y , k} ]}^{i} )}^{H} ) \qquad ( 17 )$$

In equation (17), notations [A]ᵢᵢ, [B]^{j} and [α]ₗ are used to represent the i^{th} element on the diagonal of matrix A, the j^{th} row of matrix B, and the l^{th} element of vector a, respectively.

To solve for u_{1,k}, \hat{D}_{y,k} for D in (14) and approximate σ by \hat{σ}_{1,y,k-1}. Then, to minimize the resulting f, the Lagrange multiplier method can be used and the gradient of the Lagrangian function with respect to u* set to zero, which results in:

(μ−λ+\hat{σ}_{1,y,k-1}²∥d_{x,k}∥²)u−μû_{1,k-1}−\hat{σ}_{1,y,k-1}\hat{D}_{y,k}R_{y,k}d*_{x,k}=0: (18)

where λ is the Lagrange multiplier. Using (18) and the constraint in (14), the optimal solution can be given by

$$\vert {\hat{u}}_{1 , k} = \frac{μ {\hat{u}}_{1 , k - 1} + {\hat{σ}}_{1 , y , k - 1} {\tilde{D}}_{y , k} {R}_{y , k} {d}_{x , k}^{*}}{‖ μ {\hat{u}}_{1 , k - 1} + {\hat{σ}}_{1 , y , k - 1} {\hat{D}}_{y , k} {R}_{y , k} {d}_{x , k}^{*} ‖} \qquad ( 19 )$$

Because the denominator in (19) normalizes the length of the numerator to one, (19) can be written as

$$\begin{matrix}{\tilde{u}}_{1 , k} = μ {\hat{u}}_{1 , k - 1} + {\hat{σ}}_{1 , y , k - 1} {\hat{D}}_{y , k} {R}_{y , k} {d}_{x , k}^{*} , & ( 20 a ) \\ {\hat{u}}_{1 , k} = \frac{{\tilde{u}}_{1 , k}}{‖ {\tilde{u}}_{1 , k} ‖} . & ( 20 b )\end{matrix}$$

This can then be used to substitute for û_{1,k} in (14) and solve for \hat{σ}_{1,y,k} that optimize the resulting f. Setting

$$\frac{\partial f}{\partial {\hat{σ}}_{1 , y , k}} = 0 ,$$

the optimization problem yields

$${\hat{σ}}_{1 , y , k} = \frac{max ( μ {\hat{σ}}_{1 , y , k - 1} + ℛ ( {\hat{u}}_{1 , k}^{H} {\hat{D}}_{y , k} {R}_{y , k} {d}_{x , k}^{*} ) , 0 )}{μ + {‖ {d}_{x , k} ‖}^{2}}$$

where the max(·) operator in (21) is necessary to satisfy the constraint of σ∈R⁺

Although certain aspects of the calibration algorithm have been described as being performed at Node Y, it should be understood that the steps can similarly be performed at Node X to define Dₓ and determine the BSM at Node X (e.g., q and γ).

FIG. 4 is a functional block diagram of the exemplary MIMO system 100 and further illustrates an exemplary arrangement of the BSM Algorithm, the Calibration Algorithm and transmitting/receiving operations performed at Nodes X and Y. The exemplary calibration algorithm and BSM algorithm is further described in the following Table 1. In particular, Table 1 summarizes an exemplary initialization process and the steps of the calibration algorithm performed by Nodes X and Y respectively.

TABLE 1
Summary of the self calibrating algorithms.

| | |
|---|---|
| Node X | Node Y |

Initialization

| | |
|---|---|
| Choose a random unitary vector r and send it through the channel G_{yr}HGₓᵢ. | Receive R_{y,0} = G_{yr}HGₓᵢr + N_{y,0}. ${\hat{u}}_{1 , 0} ← \frac{\text{?}}{‖ \text{?} ‖} ; {\hat{σ}}_{1 , 0} ← ‖ {R}_{y , 0} ‖ and set$ \hat{D}_{y,0} to I_{N}. |
| Receive R_{x,0} = GₓᵣH^{T}G_{yt}û_{1,0}* + N_{x,0}. ${\hat{q}}_{1 , 0} ← \frac{\text{?}}{‖ \text{?} ‖} ; {\hat{γ}}_{1 , 0} ← ‖ {R}_{x , 0} ‖ and set$ \hat{D}_{x,0} to I_{M}. | Send û_{1,0}* through the channel GₓᵣH^{T}G_{yt} |

BSM and calibration Matrix Estimations

| | |
|---|---|
| Send T_{x,k} = \hat{q}_{1,k}*d_{x,k}^{T} through G_{yr}HGₓₜ. | Receive R_{y,k} = G_{yr}HGₓₜT_{x,k} + N_{y,k}. |
| Receive R_{x,k} = GₓᵣH^{T}G_{yt}T_{y,k} + N_{x,k}. | Send T_{y,k} = û_{1,k}*d_{y,k}^{T} through |
| Use similar versions of (17), (20), and | GₓᵣH^{T}G_{yt}. |
| (21) to update \hat{D}_{x,k}, \hat{q}_{1,k}, and \hat{γ}_{1,k}, | Use(17), (20), and (21) to update \hat{D}_{yk}, û_{i,k}, and \hat{σ}_{1,k}. |

$\text{?} \text{indicates text missing or illegible when filed}$

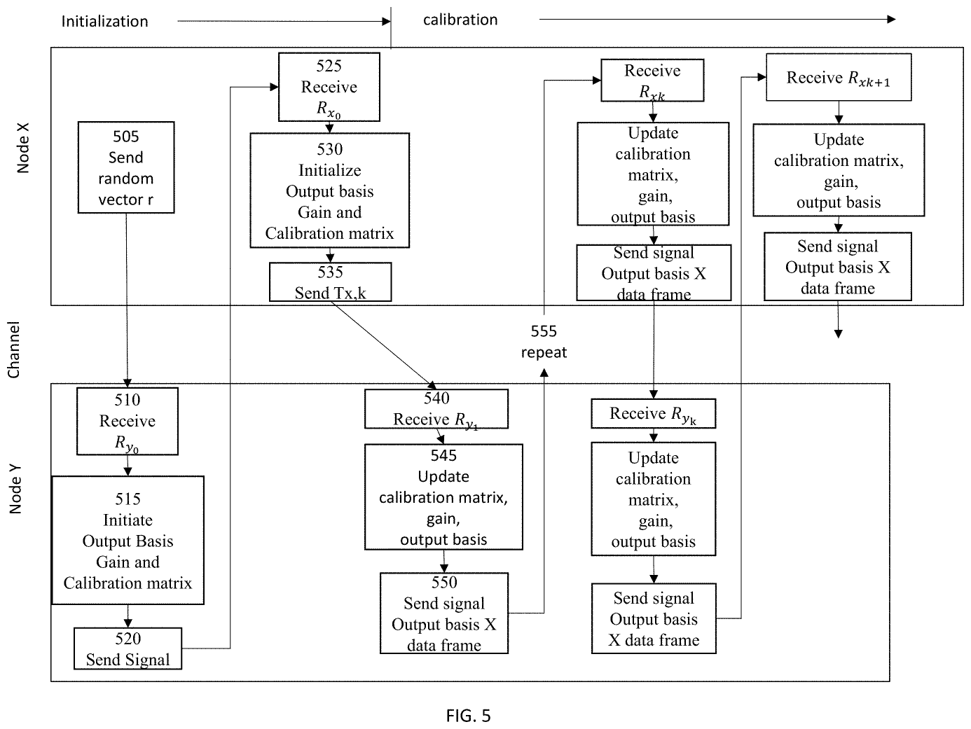

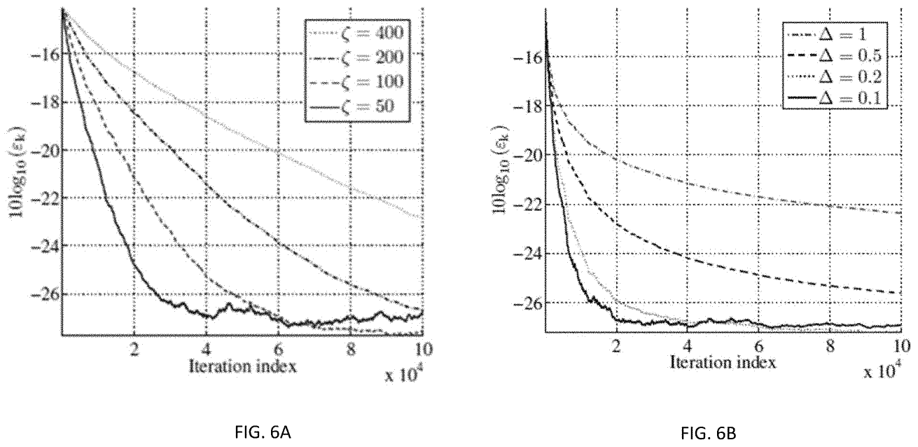

FIG. 5 is a high-level flow-diagram further illustrating the steps of the exemplary calibration algorithm shown in Table 1. For example, and without limitation, the exemplary process shown in FIG. 5 and described herein begins at Node X.

At step 505, Node X transmits a random vector r as a signal through the channel in the X→Y direction. As would be understood by those in the art, the transmission can be performed using the transmitter component 210 of the transceiver 200 provided at Node X.

At step 510, Node Y receives R_{y}_{₀}. As would be understood by those in the art, receipt of the transmitted signal can involve measuring the received signal by the receiving transceiver 200, particularly the receiver component 205.

At step 515, based on R_{y}_{₀}, Node Y initializes the output basis and gain, which can be used to transmit and receive according to the best-singular mode. For example, the beamforming module 252, can be configured to initialize the output basis and gain using the following equations:

$${\hat{u}}_{1 , 0} ← \frac{{R}_{y o}}{〚 {R}_{y o} ‖} ; {\hat{σ}}_{1 , 0} ← ‖ {R}_{y o} ‖ .$$

In addition, at step 515, the calibration module of Node Y can be configured to initialize the calibration matrix, for example, according to the following equation:

\hat{D}_{y,0}←I_{N}

At step 520, Node Y transmits the so determined

$${\hat{u}}_{1 , 0}^{*} ( e . g . , \frac{{R}_{y o} *}{‖ {R}_{y o} ‖} )$$

to Node X, as a signal through the channel in the Y→X direction. More specifically, Node Y can be configured to transmit a data symbol multiplied by the initialized calibration matrix and according to the BSM parameters determined at step 515.

At step 525, Node X receives Rₓ_{₀}. As would be understood by those in the art, receipt of the transmitted signal can involve measuring the received signal at each subchannel by the receiving transceiver, particularly, using the receiver component 205, for example.

At step 530, based on Rₓ_{₀}, Node X, specifically the beamforming module 252 and calibration module 256, define the initial setting of the output basis and gain and calibration matrix. Similar to Step 515, Node X can initialize the output basis and gain and calibration matrix using the following equations, for example:

$${\hat{q}}_{1 , 0} ← \frac{{R}_{x o}}{‖ {R}_{x o} ‖} ; {\hat{γ}}_{1 , 0} ← ‖ {R}_{x o} ‖ , {\hat{D}}_{x , 0} ← {I}_{M}$$

The foregoing initialization process serves to define an initial estimate of the output basis, gain and calibration matrix at each Node, respectively. It should be understood that alternative initialization steps could be implemented.

Subsequent to initialization, Node X and Y can repeat the steps of the exemplary calibration algorithm and/or BSM algorithm such that the nodes' respective calibration matrixes converge to a steady state where the effective forward and reverse channels are reciprocal and communication occur over the BSM, thereby improving channel capacity.

More specifically, at step 535, for iteration k=1, Node X sends T_{x,k}=\hat{q}*_{1,k}d_{x,k}^{T} to Node Y, as a signal through the channel in the X→Y direction.

At step 540, Node Y receives R_{y1}. At step 545, Node Y, specifically the beamforming module 252 and calibration module 256, calculates an updated calibration matrix, gain and output basis.

The calculation can be performed using, for example equations (17) (20) and (21) reproduced below:

$${[ {\hat{D}}_{y , k} ]}_{ii} = \frac{1}{ζ + {‖ {[ {R}_{y , k} ]}^{i} ‖}^{2}} ( {ζ [ {\hat{D}}_{y , k - 1} ]}_{ii} + {{\hat{σ}}_{1 , k - 1} [ {\hat{u}}_{1 , k - 1} ]}_{i} {{d}_{x , k}^{T} ( {[ {R}_{y , k} ]}^{i} )}^{H} )$$

$${\tilde{u}}_{1 , k} = μ {\hat{u}}_{1 , k - 1} + {\hat{σ}}_{1 , y , k - 1} {\hat{D}}_{y , k} {R}_{y , k} {d}_{x , k}^{*} \\ {\hat{u}}_{1 , k} = \frac{{\tilde{u}}_{1 , k}}{‖ {\tilde{u}}_{1 , k} ‖} . \\ {\hat{σ}}_{1 , y , k} = \frac{max ( μ {\hat{σ}}_{1 , y , k - 1} + ℛ ( {\hat{u}}_{1 , k}^{H} {\hat{D}}_{y , k} {R}_{y , k} {d}_{x , k}^{*} ) , 0 )}{μ + {‖ {d}_{x , k} ‖}^{2}}$$

Notations [A]ᵢᵢ, [B]^{j} and [α]ₗ are used to represent the i^{th} element on the diagonal of matrix A, the j^{th} row of matrix B, and the l^{th} element of vector a, respectively. k represents the number of iteration. In the first iteration, k=1, and the k−1 iteration refers to the preceding initialization iteration. ζ represents the weight factor. û_{1,k-1} represents the normalized estimation of the output vector calculated by Node Y at iteration k−1. \hat{D}_{y,k-1} represents the estimation of the calibration matrix calculated by Node Y at iteration k−1. R_{y,k} represents the received signal at Node Y for the kth iteration. d_{x,k} represents the sent data frame sent by Node X at iteration k, as can be determined by Node Y from the received signal or is otherwise known. \hat{σ}_{1,y,k-1} represents the estimation of the gain vector calculated by Node Y at iteration k−1.

At step 650, Node Y sends T_{y,k}=û*_{1,k}d_{yk} ^{T} to Node X as signal through the channel in the Y→X direction i.e., GₓᵣH^{T}G_{yt}.

As shown at step 550, Node X and Y can then repeat the foregoing steps 535-550 a suitable number of iterations such that the nodes' respective calibration matrixes reach convergence and the calibrated channel in the direction of X->Y and the calibrated channel in the direction of Y->X are reciprocal.

### Simulation Examples and Results

In following test cases, the performance of the exemplary calibration algorithm is demonstrated using computer simulations. In performing these evaluations it has been assumed that an N×M MIMO system operates in a slow fading environment. The channel matrix H∈C^{N×M} is unknown to both, the transmitter and the receiver and is generated randomly for each run. The elements of H are assumed to be i.i.d. circularly symmetrical complex Gaussian random variables with zero mean and unit variance. Elements of Gₓₜ, Gₓᵣ, G_{yt}, and G_{yr} are i.i.d. complex numbers of the form g=ae^{jθ}, where a is a drawn from a random variable uniformly distributed between 1−α and 1+α, where α is a chosen parameter that determines how far the amplitude of g can deviate from the ideal value “1” and θ is drawn from a random variable uniformly distributed between −θ_{d} and +θ_{d}, where θ_{d} is a chosen parameter that dictates how much the phase of g is allowed to deviate (in radian) from the nominal value “0”. The Signal to Noise Ratio (SNR) is defined as the transmitted power to the received noise variance, (i.e., 1/v² since the transmitted power is normalized to 1).

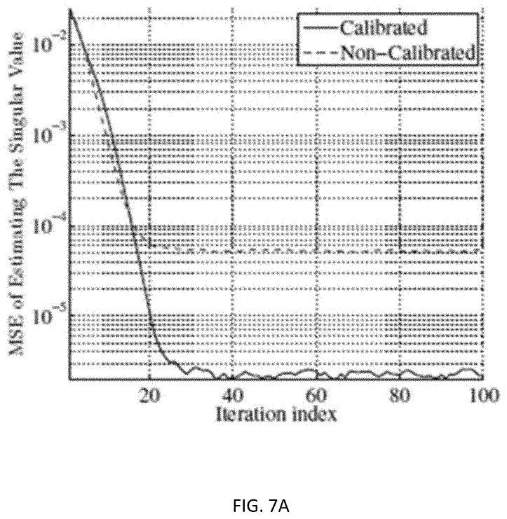

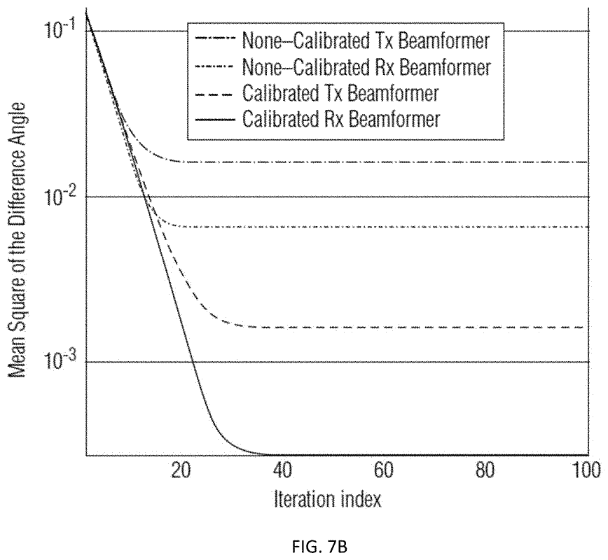

FIG. 7A and FIG. 7B are diagrams illustrating the performance of the calibration algorithm in estimating and updating the calibration matrices, Dx and Dy. The tests are performed assuming that the transmitted data is known at the receiver to evaluate the training mode performance of the calibration algorithm. The number of antennas has been fixed to 2×2 and simulations run for different values of ζ∈{50, 100, 200, 400} for SNR of 20 dB. The mismatch parameters are set to α=0.05 and θ_{d}=0.1744 rad=10 degrees. In the simulation, each node sends only one symbol at a time to the other node, that is the frame length of the training data is one symbol.

In order to evaluate the estimation error of the calibration matrix D, the reciprocity criterion (12) is considered as the performance measure. In other words, the performance measure is the Frobenius norm of the difference between the transmit filter matrix and the multiplication of the calibration matrix and the receive filter matrix. Mathematically, this can be written as

ε_{x,k}=∥\hat{D}_{x,k}Gₓᵣ−Gₓₜ∥²

ε_{y,k}=∥\hat{D}_{y,k}G_{yr}−G_{yt}∥²

where εₓₖ and ε_{yk} are the performance figures at iteration k at nodes X and Y, respectively.

During simulation, the channel realization is changed every 100 iterations and, during which period, the calibration matrices are updated twice. One exemplary reason for updating the calibration matrices periodically and less frequently is that it can be preferable to wait for a good estimate of the singular mode before calibration occurs. Accordingly, in one or more embodiments, the nodes can be configured to update the calibration matrices according to a prescribed period or interval rather than with each and every signal.

### Results—Filter Mismatch Calibration Error with a Fixed or Varying Step-Size Value of ζ

FIG. 7A is a chart illustrating the performance of the calibration algorithm versus the iteration index for different values of at an SNR of 20 dB, wherein ε is expressed in dB. Specifically FIG. 7A illustrates the filter mismatch calibration error versus iteration index. In this exemplary test, during the training process, the values of μ is fixed to 5. It can be noted that, as the value of the parameter ζ increases, the convergence of the error curve slows down and the variation of the average error gets smaller consistent with adaptive algorithms involving an estimation step size. Accordingly, in some configurations, the exemplary systems and methods for calibration can be configured to adjust the step-size value to mitigate slowness in the calibration process. For instance, to increase convergence speed, the calibration process can be initially configured to start with a small value of ζ that is increased every time the calibration matrix is updated.

In other words, the calibration module can be configured to start with initial vale of ζ₁=ζᵢ, wherein represents the “initial value of ζ.” Then, the function ζn=ζₙ₊₁+Δ, wherein Δ represents the increment value, can be used to increment each time the calibration matrix is updated. This exemplary configuration provides two advantages, the first is the fast decline of the calibration error during the first iterations (as long as ζ is relatively small), and the second (when the value of ζ gets larger) is the reduction of the value and the fluctuation of the calibration error. FIG. 7B illustrates calibration performance, particularly, the performance of the calibration algorithm versus the iteration index when ζᵢ=10 and where ζ increments at different step sizes Δ=0.1, 0.2, 0.5 or 1 and where SNR=200dB, μ=5, α=0.05 and θ_{d}=10 degrees.

### Results—Post-Calibration Performance

To further evaluate the performance of the calibration algorithm, simulations evaluating the evaluate the performance of an exemplary BSM semi-blind algorithm before and after implementing the calibration matrices obtained in the previous subsection. Note that the BSM algorithms proposed in NPL Gazoor-AlSuhaili are special cases of the algorithms proposed in this disclosure when we set the calibration matrices at Node X and Y to I_{M} and I_{N}, respectively. The performance formulas used here are defined in view of the fact that there are two different BSMs for the forward and the reverse channels.

In particular, at Node Y, the transceiver is required to estimate (σ₁, u₁, p₁) of the channel matrices given by H_{X→Y}=G_{yr}HGₓₜ=UΣV^{H} and H_{Y→X}=GₓᵣH^{T}G_{yt}=QΓP^{H} when not implementing the calibration matrices and, when implementing the calibration matrices, (σ′₁, u′₁, p′₁) of the channel matrices given by H′_{X→Y}=\hat{D}_{y}G_{yr}HGₓₜ=U′Σ′V′^{H} and H′_{Y→X}=\hat{D}ₓGₓᵣH^{T}G_{yt}=Q′Γ′P′^{H}. It can be noted that Node Y in both cases is capable of estimating two parameters, that is, (σ1; u1) in the case of not implementing the calibration matrices and (σ′₁; u′₁) in the case of implementing them. Therefore, the performance measures can be given by

$${δ}_{k} = \vert \frac{{\hat{σ}}_{1 , k} - {σ}_{1}}{{σ}_{1}} \vert , \\ {δ}_{k}^{′} = \vert \frac{{\hat{σ}}_{1 , k}^{′} - {σ}_{1}^{′}}{{σ}_{1}^{′}} \vert , \\ {φ}_{yt , k} = ∠ ( {p}_{1} , {\hat{u}}_{1 , k}^{*} ) = {cos}^{- 1} ( \vert {p}_{1}^{H} {\hat{u}}_{1 , k}^{*} \vert ) , \\ {φ}_{yr , k} = ∠ ( {u}_{1} , {\hat{u}}_{1 , k} ) = {cos}^{- 1} ( \vert {u}_{1}^{H} {\hat{u}}_{1 , k} \vert ) , \\ {φ}_{yt , k}^{′} = ∠ ( {p}_{1}^{′} , {( {\hat{u}}_{1 , k}^{′} )}^{*} ) = {cos}^{- 1} ( \vert {{p}_{1}^{′H} ( {\hat{u}}_{1 , k}^{′} )}^{*} \vert ) , \\ {φ}_{yr , k}^{′} = ∠ ( {u}_{1}^{′} , {\hat{u}}_{1 , k}^{′} ) = {cos}^{- 1} ( \vert {u}_{1}^{′H} {\hat{u}}_{1 , k}^{′} \vert ) ,$$

where δ and δ′ represent the normalized estimation error of σ₁ and σ′₁, respectively. ϕ_{yt,k} and ϕ′_{yt,k} represent the angle (in radian) between the estimates (û*_{1,k} and (û′_{1,k})) and the optimal transmit beamformers (input singular vector p₁ and p′₁, respectively). ϕ_{yr,k} and ϕ′_{yr,k} represent the angle (in radian) between the estimates (û*_{1,k} and (û′_{1,k})) and the optimal beamformers (output singular vectors u₁ and u′₁ respectively). In particular, we use the average of the squared of the above mentioned quantities as our performance measures.

FIG. 8A and FIG. 8B are diagrams illustrating the improvement of the calibration on the performance of the semi-blind BSM algorithm in estimating the singular values as well as the input and output vectors achieved by implementing the calibration matrices. regarding the mean squared of the difference angle between the optimal input and output vectors of the BSM semi-blind algorithm, this diagram is generated in connection with testing under specific test parameters, specifically μ=2000, framelength L=1000. The mean square of 6 and o′is referred to as the MSE of estimating the singular value, and the mean square of ϕ_{yt,k}ϕ′_{yt,k}, ϕ_{yr,k}, and ϕ′_{yr,k} is referred to as the Mean Square of the difference angle.

In view of the foregoing it can be appreciated that the disclosed systems and methods for filter mismatch calibration effectively address the problem of non-reciprocity due to the mismatch between the transmit and the receive filters of a closed loop MIMO communication system employing, for example, a variation of the BSM algorithm provided in NPL Gazor-AlSuhaili. In addition, it can be appreciated that the exemplary algorithm enables self-calibration in which a communicating node adaptively compensates for such a mismatch without requiring any additional RF circuitry. Moreover, embodiments of the calibration process can use the observed, received signal for estimating the complex gains that are required to compensate for such a mismatch. The compensation gains during the normal operation of the system are fixed and thereby allow for matching with all filters. Furthermore, the computer simulations illustrate that the calibration algorithm converges during the calibration process and provides significant improvement compared with a non-calibrated system.

It should be understood that various combination, alternatives and modifications of the present disclosure could be devised by those skilled in the art. The present disclosure is intended to embrace all such alternatives, modifications and variances that fall within the scope of the appended claims.

It should be understood that embodiments of the present disclosure may be implemented by software, by hardware, or by any combination of software and/or hardware as may be appropriate for specific applications or design requirements. In some embodiments, the system of the disclosure can further include general, multi-purpose and/or specific processors, circuits, logic systems, operators, circuitry, blocks, units and/or sub-units that can perform any operation, or any combination of operations, described above. In some embodiments of the disclosure, the system can further include memory units, buffers and/or registers for temporary and/or permanent storage of data. These units (e.g., processor and memory units), or any combination thereof, can be referred to herein as “circuitry,” and can be internal and/or external to a communication node, in whole or in part. Accordingly, embodiments of the disclosure can include an article comprising a storage medium having stored thereon instruction that, when executed by a processing device, perform the steps of the exemplary power allocation algorithm for allocating transmission power at a communication node by, inter alia, multiplying one or more of a plurality of subcarriers by a calculated respective subcarrier weight, in accordance with the disclosed embodiments.

The flowchart and block diagrams in the figures illustrate the architecture, functionality, and operation of possible implementations of systems, methods and computer program products according to various embodiments and arrangements. In this regard, each block in the flowchart or block diagrams can represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It should be further appreciated that more or fewer operations can be performed than shown in the figures and described. It is to be understood that like numerals in the drawings represent like elements through the several figures, and that not all components and/or steps described and illustrated with reference to the figures are required for all embodiments or arrangements.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

While the invention has been particularly shown and described with reference to a preferred embodiment thereof, it will be understood by those skilled in the art that various changes in form and details may be made therein without departing from the spirit and scope of the disclosure. Therefore, the scope of the invention is indicated by the appended claims, rather than by the foregoing description. All changes that come within the meaning and range of equivalency of the claims are to be embraced within their scope.

What is claimed is:

1. A method for calibrating filter mismatch in a MIMO communication system, comprising:
receiving a first signal at a first communication node, wherein the signal is transmitted by a second communication node to the first node through a wireless communication channel;
determining, by the first node from the received signal, an estimate of an output singular vector and a gain value of a channel matrix from the first communication node to the second communication node; and
calculating, by the first node, an estimate of a calibration matrix, wherein the calibration matrix estimate is calculated as a function of the received signal, a previous estimate of the output singular vector, a previous estimate of the gain value and a previous estimate of the calibration matrix; and
transmitting, by the first node, a second signal over the channel, wherein the signal is transmitted according to the estimate of the output singular vector, gain value and channel matrix calculated by the first node.

2. The method of claim 1, further comprising:
performing, by the second node based on the second signal, the receiving, determining, calculating and transmitting steps.

3. The method of claim 2, wherein the first node and second node communicate back and forth and respectively perform the receiving, determining, calculating, and transmitting steps based on subsequent received signals, thereby adaptively updating the calibration matrix and the output singular vector and gain value with each iteration.

4. The method of claim 1, wherein the estimate of the calibration matrix is calculated using a function that places a greater weight on the previous estimate of the calibration matrix than the received signal.

5. The method of claim 1, wherein the estimate of the calibration matrix is calculated according to the following equation:
$${[ {\hat{D}}_{y , k} ]}_{ii} = \frac{1}{ζ + {‖ {[ {R}_{y , k} ]}^{i} ‖}^{2}} ( {ζ [ {\hat{D}}_{y , k - 1} ]}_{ii} + {{\hat{σ}}_{1 , k - 1} [ {\hat{u}}_{1 , k - 1} ]}_{i} {{d}_{x , k}^{T} ( {[ {R}_{y , k} ]}^{i} )}^{H} )$$
wherein notations [A]ᵢᵢ, [B]^{j} and [α]ₗ are used to represent the i^{th} element on the diagonal of matrix A, the j^{th} row of matrix B, and the l^{th} element of vector a, respectively, and wherein k represents the number of iteration, ζ represents the weight factor put on the previous estimation of the gain vector, û_{1,k-1} represents the normalized estimation of the output vector calculated by the first node at iteration k−1, \hat{D}_{y,k-1} represents the estimation of the calibration matrix calculated by the first node at iteration k−1, R_{y,k} represents the received signal at the first communication node at the kth iteration, d_{x,k} represents the sent data frame from the second communication node, \hat{σ}_{1,y,k-1} represents the estimation of the gain vector calculated by the first node at iteration k−1.

6. The method of claim 5, wherein at iteration k=1, the previous estimate of the calibration matrix Dₖ₋₁=I_{N}, wherein N represents the number of antennas at the second communication node.

7. The method of claim 1, wherein the estimate of the gain vector is calculated according to the following equation:
$${\hat{σ}}_{1 , y , k} = \frac{max ( μ {\hat{σ}}_{1 , y , k - 1} + ℛ ( {\hat{u}}_{1 , k}^{H} {\hat{D}}_{y , k} {R}_{y , k} {d}_{x , k}^{*} ) , 0 )}{μ + {‖ {d}_{x , k} ‖}^{2}}$$
wherein k represents the number of iteration, μ represents a weight factor put on the previous estimation of the gain vector, û_{1,k}^{H} represents the transformed, normalized estimation of the output vector for the kth iteration, \hat{D}_{y,k} represents the estimation of the calibration matrix for the kth iteration, R_{y,k} represents the received signal at the kth iteration, d_{x,k} represents the sent data frame from the second communication node, \hat{σ}_{1,y,k-1} represents the previous estimate of the gain vector.

8. The method of claim 9, wherein at iteration k=1, the previous estimate of the gain vector is defined according to the following equation:
σ=∥R∥
wherein R represents the received vector signal.

9. The method of claim 1, wherein the estimate of the output singular vector is calculated according to the following equations:
$${\tilde{u}}_{1 , k} = μ {\hat{u}}_{1 , k - 1} + {\hat{σ}}_{1 , y , k - 1} {\hat{D}}_{y , k} {R}_{y , k} {d}_{x , k}^{*} , \\ {\hat{u}}_{1 , k} = \frac{{\tilde{u}}_{1 , k}}{‖ {\tilde{u}}_{1 , k} ‖} .$$
wherein k represents the kth estimation, u represents the previous estimation of the output singular vector, μ represents a weight factor put on the previous estimation of the output singular vector, a represents a gain value of the channel matrix, D represents the calibration matrix, R represents the received signal, d represents the transmitted data frame.

10. The method of claim 9, wherein at iteration k=1, the output singular value is defined according to the following equation:
u=R/∥R∥
wherein R represents the received signal vector at the first communication node.

11. The method of claim 1, further comprising:
determining, by the first node based on the received first signal, an estimate of the data frames as transmitted from the second communication node, wherein the estimate of received data frames are determined according to the equation:
$${\hat{d}}_{x}^{T} = \frac{1}{{σ}_{1}} {u}_{1}^{H} {R}_{y} ,$$
wherein R represents is the received signal vector, u represents the previous estimation of the singular value, σ represents a singular value gain of the channel matrix.

12. The method of claim 4, wherein weight factor ζ is one or more of: a fixed value, and a value that is adjusted as a function of a number of iterations.

13. A MIMO communication system, comprising:
a first communication node comprising:
a receiver configured to receive signals transmitted over a wireless communication channel, including a first signal transmitted by a second node;
a beamforming module encoded in a processor of the node, wherein the beamforming module configures the processor to: determine, from the received signal, an estimate of an output singular vector and a gain value of a channel matrix from the first node to the second node;
a calibration module that configures the processor to calculate, based on the received signal, an estimate of a calibration matrix, wherein the calibration matrix estimate is calculated as a function of the received signal, a previous estimate of the output singular vector, a previous estimate of the gain value and a previous estimate of the calibration matrix; and
a transmitter configured to transmit a second signal over the channel, wherein the signal is transmitted according to the estimate of the output singular vector, gain value and channel matrix calculated by the first node weighted according said subcarrier weights over the sub carriers.

14. The system of claim 13, further comprising:
the second node, wherein the second node is a MIMO communication node comprising a respective instance of the receiver, the beamforming module, the calibration module and the transmitter.

15. The system of claim 14, wherein the first and second node are configured to execute an iterative beamforming and calibration algorithm which causes the first and second node to communicate back and forth a plurality of iterations and, with each received signal, the receiving node adaptively updates the calibration matrix by re-calculating the estimates of the calibration matrix, the output singular vector and gain value, followed by transmitting a signal back to the other node as a function of the updated estimates of the calibration matrix, the output singular vector and gain value.

16. The system of claim 15, wherein the calibration algorithm is implemented a number of iterations sufficient for the estimate of the calibration matrix to reach convergence.

17. The system of claim 16, wherein the updated calibration matrix is calculated using a function that places a greater weight on the previous calibration matrix estimate than the received signal.
